(19) United States
(12) Patent Application Publication
(10) Pub. No.: US 2010/0024868 A1
(43) Pub. Date: Feb. 4, 2010

(54) SOLAR RADIATION COLLECTOR

(75) Inventors: Itay Baruchi, Tel Aviv (IL); Gonen Fink, Tel Aviv (IL)

Correspondence Address: OLIFF & BERRIDGE, PLC, P.O. BOX 320850, ALEXANDRIA, VA, 22320-4850, US

(73) Assignee: PYTHAGORAS SOLAR INC., Wilmington, DE (US)

(21) Appl. No.: 12/518,720

(22) PCT Filed: Dec. 6, 2007
(86) PCT No.: PCT/IL2007/001510

§ 371 Date: Jun. 11, 2009

Related U.S. Application Data
(60) Provisional application No. 60/869,737, filed on Dec. 13, 2006.
(60) Provisional application No. 60/929,603, filed on Jul. 5, 2007.

(51) Int. Cl. H01L 31/052; H01L 31/00

(52) U.S. Cl. 136/246; 136/259

(57) ABSTRACT

A solar radiation collector comprising a concentrator and a photovoltaic cell, the concentrator comprising at least a prismatic primary portion, the primary portion comprising primary entrance aperture having a perimeter, an outer surface adapted for receiving radiation, and a inner surface; a primary receiver plane; sidewalls, meeting the primary entrance aperture along at least a portion of the perimeter; and a reflective bottom surface. The primary portion is adapted to utilize total internal reflection at least from the inner surface of the primary entrance aperture to concentrate radiation entering through the primary entrance aperture toward the primary receiver plane. The primary entrance aperture comprises a reference area defined as the area thereof between two lines, each of the lines being the intersection between the primary entrance aperture and an imaginary plane which is perpendicular to both the primary entrance aperture and an extreme end of the primary receiver plane; the total area of the primary entrance aperture substantially exceeding that of the reference area.

### FIELD OF THE INVENTION

This invention relates to solar radiation collectors, and especially to those which are adapted to concentrate the radiation.

### BACKGROUND OF THE INVENTION

It is well known that solar radiation can be utilized by various methods to produce usable energy. One method involves the use of a photovoltaic cell, which is adapted to convert solar radiation to electricity.

It is further appreciated that the cost per unit power for producing electricity using photovoltaic cells can be decreased by concentrating the sunlight. In this way, the same amount of sunlight can impinge a smaller, and thus cheaper, photovoltaic cell, from which a similar or equal amount of electricity can be extracted.

Many methods and devices for concentrating solar radiation are known in the art. For example, U.S. Pat. No. 6,294,723 to Uematsu, et al., discloses a photovoltaic module including a plurality of concentrators each having a light-incident plane and a reflection plane, and photo detectors each being in contact with one of the concentrators, which is capable of effectively trapping light and effectively generating power throughout the year even if the module is established such that sunlight at the equinoxes is made incident on the light-incident planes not perpendicularly but obliquely from the right, upper side, for example, in the case where the module is established in contact with a curved plane of a roof or the like. In this module, each concentrator is formed into such a shape as to satisfy a relationship in which the light trapping efficiency of first incident light tilted rightwardly from the normal line of the light-incident plane in the cross-section including the light-incident plane, reflection plane and photo detector is larger than the light trapping efficiency of second incident light tilted leftwardly from the normal line in the above cross-section, and these concentrators are arranged in one direction.

US 2006/0283495 to Gibson discloses a solar cell device structure and method of manufacture. The device has a back cover member, which includes a surface area and a back area. The device also has a plurality of photovoltaic regions disposed overlying the surface area of the back cover member. In a preferred embodiment, the plurality of photovoltaic regions occupying a total photovoltaic spatial region. The device has an encapsulating material overlying a portion of the back cover member and a front cover member coupled to the encapsulating material. An interface region is provided along at least a peripheral region of the back cover member and the front cover member. A sealed region is formed on at least the interface region to form an individual solar cell from the back cover member and the front cover member. In a preferred embodiment, the total photovoltaic spatial region/the surface area of the back cover is at a ratio of about 0.80 and less for the individual solar cell.

In addition, solar concentrators are disclosed in the following publications:
Ideal Prism Solar Concentrators, by D. R. Mills and J. E. Giutronich (published in Solar Energy, Vol. 21, pp. 423-430 by Pergamon Press, Ltd., Great Britain;
A New Static Concentrator PV Module with Bifacial Cells for Integration on Facades: The PV Venetian Store, by J. Alonso, et al., appearing in Photovoltaic Specialists Conference, 2002. Conference Record of the Twenty-Ninth IEEE, 19-24 May, 2002, pp. 1584-1587; and
High Efficiency Photovoltaic Roof Tile with Static Concentrator, by S. Bowden, et al., appearing in Photovoltaic Energy Conversion, 1994., Conference Record of the Twenty Fourth; IEEE Photovoltaic Specialists Conference—1994, 1994 IEEE First World Conference on, 5-9 December, 1994, pp. 774-777.

### SUMMARY OF THE INVENTION

According to one aspect of the present invention, there is provided solar radiation collector comprising a concentrator (such as a dielectric filled concentrator) and a photovoltaic cell, the concentrator comprising at least a prismatic primary portion, the primary portion:
comprising:
   a primary entrance aperture having a perimeter, an outer surface adapted for receiving radiation (such as sunlight), and a inner surface;
   a primary receiver plane;
   sidewalls, meeting the primary entrance aperture along at least a portion of the perimeter; and
   a reflective bottom surface; and
being adapted to utilize total internal reflection at least from the inner surface of the primary entrance aperture to concentrate radiation entering through the primary entrance aperture toward the primary receiver plane;
   wherein the primary entrance aperture comprises a reference area defined as the area thereof between two lines, each of the lines being the intersection between the primary entrance aperture and an imaginary plane which is perpendicular to both the primary entrance aperture and an extreme end of the primary receiver plane (geometrically, the reference area may be formed as a rectangle on the primary entrance aperture, wherein one side thereof is coincident with the intersection between the primary entrance aperture and the primary receiver plane, for example when the intersection of the primary receiver plane and the primary entrance aperture is parallel to an opposite side of the perimeter); the total area of the primary entrance aperture substantially exceeds that of the reference area, i.e., at least a portion of the perimeter substantially deviates, i.e., extends outwardly from, the reference area. Therefore, its concentration is more than a reference solar radiation collector of a similar design whose entrance aperture is substantially coincident with the reference area.

It will be appreciated that hereafter in the specification and claims, the terms prism and prismatic are to be understood as referring to a transparent solid body, and not being limited to any specific shape.

It will further be appreciated that hereafter in the specification and claims, the term aperture is to be understood as a light incident surface, i.e., one through which light enters, and not necessarily as having a physical hole or opening.

The solar radiation collector may be further embodied by any one or more of the following in combination, mutatis mutandis.

The solar radiation collector may further comprise a secondary portion which:
has a secondary entrance aperture which is substantially coincident with the primary receiver plane;
comprises the photovoltaic cell; and
is adapted for directing radiation entering via the secondary entrance aperture toward the photovoltaic cell.

The secondary portion may be a prism. The primary and secondary portions may be integrally formed as a single prism.

The secondary portion may comprise at least one reflective surface having at least one cross section comprising at least a parabolic portion (i.e., it is formed as a compound parabolic concentrator [CPC]).

The photovoltaic cell may be bifacial, the reflective surface of the secondary portion being formed having a central section, formed as a circular arc, and two parabolic sections, such that:
the foci of the two parabolic sections are coincident with one another and with the center of the arc and are within the secondary portion;
a proximal end of each of the parabolic sections is coincident with one end of the central section;
a distal end of each of the parabolic sections is coincident with one end of the reflective plane;
the acute angle formed between a first line connecting the center of the arc and a distal end of one of the parabolic sections and a second line extending from the midpoint of the arc beyond the center thereof is equal to half of the acceptance angle of the secondary portion; and
the photovoltaic cell extends at least from the center of the arc to a point of the central section of the reflective surface;
   the acceptance angle of the secondary portion being substantially equal to the exit angle of the primary portion.

The photovoltaic cell may project beyond the reflective surface.

A first edge of the photovoltaic cell may be substantially coincident with a first edge of the secondary entrance aperture, the reflective surface being formed having a first section being an arc, and a second section being parabolic, such that:
the photovoltaic cell extends between a first end of the first section and a first end of the secondary entrance aperture of the secondary portion;
the second section extends between a second end of the first section and a second end of the secondary entrance aperture;
the focus of the parabolic of the second section is coincident with the first end of the first section; and
the acute angle formed between a first line extending along the secondary entrance aperture and a second line which is perpendicular to one which extends from the first end of the first section to the second end of the first section is equal to half of the acceptance angle of the secondary portion;
   the acceptance angle of the secondary portion being substantially equal to the exit angle of the primary portion.

The photovoltaic cell may be monofacial. Alternatively, it may be bifacial and transparent to infrared radiation, the solar radiation collector further comprising an up-conversion material adapted to reradiate light irradiating thereupon as radiation containing spectral components in the visible range, and disposed such that the reradiated light impinges upon the photovoltaic cell.

The photovoltaic cell may be substantially parallel to the primary entrance aperture.

The reflective surface of the secondary portion may be a dichroic filter adapted to allow at least infrared radiation to pass therethrough.

Sidewalls of the secondary portion may be inclined toward one another in a direction which is away from the secondary entrance aperture (i.e., so that, in plan view, the secondary portion is trapezoidal).

At least two sidewalls of the primary portion, adjacent to the primary receiver plane, may be planar, the sidewalls of the secondary portion being coplanar with them.

The primary entrance aperture of the solar radiation collector is of a shape which comprises at least four sides, wherein:
a first side is coincident with an edge of the primary receiver plane; and
a second and a third side are each coincident with an edge of one of the sidewalls.

The primary entrance aperture may be formed as a hexagon; the first, second, and third sides thereof constituting adjacent sides thereof, the first side being between the second and third sides.

The second and third sides may each be adjacent to the first side at proximal ends thereof, each being formed as a parabolic section, such that:
the focus of the parabola forming the second side is coincident with the intersection between the first and third sides;
the focus of the parabola forming the third side is coincident with the intersection between the first and second sides; and
the acute angle formed between a first line extending between the proximal end of the second side and the focus of the second side and a second line extending perpendicularly to the first side is equal to half of the acceptance angle of the primary portion.

The sidewalls may project perpendicularly from the primary entrance aperture.

Alternatively, at least a part of at least one of the sidewalls may be disposed such that is forms an acute angle with the primary receiver aperture. The part may meet the primary receiver aperture. The at least one sidewall may comprise a primary receiver aperture-contacting portion which meets the primary receiver aperture at a non-acute angle, the part meeting the primary receiver aperture-contacting portion.

The primary entrance aperture may be planar.

The primary entrance aperture may be of a shape which may be tessellated with other solar radiation collectors having the same shape without leaving gaps therebetween.

The bottom reflective surface may be a dichroic filter adapted to allow at least infrared radiation to pass therethrough.

According to one option, the primary portion may have a cross-section, taken along a plane which is perpendicular to the primary receiver plane, which is right-triangular, such that:
a first cathetus thereof is coincident with the primary receiver plane;
a second cathetus thereof is coincident with the reflective bottom surface; and
the hypotenuse thereof is coincident with the primary entrance aperture of the solar radiation collector.

According to another option, the primary portion may have a cross-section, taken along a plane which is perpendicular to the primary receiver plane, which is right-triangular, such that:
a first cathetus thereof is coincident with the primary entrance aperture of the solar radiation collector;
a second cathetus thereof is coincident with the primary receiver plane; and
the hypotenuse thereof is coincident with the reflective bottom surface.

According to either of the above two options, the angle between the hypotenuse and the second cathetus may be given by:

$$θ = \frac{{θ}_{c} - {sin}^{- 1} [ \frac{1}{n} sin ( \frac{π}{2} - {θ}_{a} ) ]}{2} ,$$

where:
θ is the angle between the hypotenuse and the second cathetus;
θ_{c} is the critical angle for total internal reflection of the prism;
n is the refractive index of the prism; and
θₐ is the maximum acceptance elevation angle, in radians, of the sun at the location where the solar radiation collector is installed.

The primary entrance aperture of the solar radiation collector may be of a shape which comprises at least four sides, wherein:
a first side is coincident with an edge of the primary receiver plane; and
a second and a third side are each coincident with an edge of one of the sidewalls.

The primary entrance aperture may be formed as a hexagon; the first, second, and third sides thereof constituting adjacent sides thereof, the first side being between the second and third sides. The sidewalls may project perpendicularly from the primary entrance aperture. The primary entrance aperture may be planar.

The primary entrance aperture may be of a shape which may be tessellated with other solar radiation collectors having the same shape without leaving gaps therebetween.

According to another aspect of the present invention, there is provided a solar radiation collector comprising a concentrator and a photovoltaic cell, the concentrator comprising at least a prismatic primary portion and a secondary portion, the primary portion:
comprising:
   a primary entrance aperture having an outer surface adapted for receiving radiation, and a inner surface;
   a primary receiver plane;
   reflective sidewalls, defining with the primary entrance aperture an upper edge; and
   a reflective bottom surface; and
being adapted to utilize total internal reflection from the inner surface of the primary entrance aperture to concentrate radiation entering through the primary entrance aperture toward the primary receiver plane;
   the secondary portion:
having a secondary entrance aperture which is substantially coincident with the primary receiver plane;
having a secondary receiver plane which is transverse to the secondary entrance aperture;
comprising the photovoltaic cell along the receiver plane; and
comprising at least one reflective surface having a cross-section, taken along a plane which is perpendicular to both the secondary entrance aperture and the secondary receiving plane, which is parabolic.

It will be appreciated that the term “transverse” should be understood in its broadest sense, i.e., that the two planes are at an angle to one another, such that all cross-sections of the two planes taken along planes which are perpendicular to both planes are similar.

The solar radiation collector may be further embodied by any one or more of the following in combination, mutatis mutandis.

The secondary portion may be a prism. In addition, the primary and secondary portions may be integrally formed as a single prism.

The photovoltaic cell may be bifacial, the reflective surface of the secondary portion being formed having a central section, formed as a circular arc, and two parabolic sections, such that:
the foci of the two parabolic sections are coincident with one another and with the center of the arc and are within the secondary portion;
a proximal end of each of the parabolic sections is coincident with one end of the central section;
a distal end of each of the parabolic sections is coincident with one end of the reflective plane;
the acute angle formed between a first line connecting the center of the arc and a distal end of one of the parabolic sections and a second line extending from the midpoint of the arc beyond the center thereof is equal to half of the acceptance angle of the compound parabolic concentrator; and
the photovoltaic cell extends at least from the center of the arc to a point of the central section of the reflective surface.

The photovoltaic cell may project beyond the reflective surface.

A first edge of the photovoltaic cell may be substantially coincident with a first edge of the secondary entrance aperture, the reflective surface being formed having a first section being an arc, and a second section being parabolic, such that:
the photovoltaic cell extends between a first end of the first section and a first end of the secondary entrance aperture of the secondary portion;
the second section extends between a second end of the first section and a second end of the secondary entrance aperture;
the focus of the parabolic of the second section is coincident with the first end of the first section; and
the acute angle formed between a first line extending along the secondary entrance aperture and a second line which is perpendicular to one which extends from the first end of the first section to the second end of the first section is equal to half of the acceptance angle of the compound parabolic concentrator.

The photovoltaic cell may be monofacial. Alternatively, it may be bifacial and transparent to infrared radiation, the solar radiation collector further comprising an up-conversion material adapted to reradiate light irradiating thereupon as radiation containing spectral components in the visible range, and disposed such that the reradiated light impinges upon the photovoltaic cell.

The photovoltaic cell may be substantially parallel to the primary entrance aperture.

The reflective surface of the secondary portion may be a dichroic filter adapted to allow at least infrared radiation to pass therethrough.

According to another aspect of the present invention, there is provided a solar radiation collector comprising a concentrator and a photovoltaic cell, the concentrator comprising at least a prismatic primary portion and a secondary portion, the primary portion:
comprising:
   a primary entrance aperture having an outer surface adapted for receiving radiation, and a inner surface;
   a primary receiver plane;
   reflective sidewalls, defining with the primary entrance aperture an upper edge; and
   a reflective bottom surface; and
being adapted to utilize total internal reflection from the inner surface of the primary entrance aperture to concentrate radiation entering through the primary entrance aperture toward the primary receiver plane;
   the secondary portion:
having a secondary entrance aperture which is substantially coincident with the primary receiver plane;
having a secondary receiver plane which is transverse to the secondary entrance aperture; and
comprising the photovoltaic cell along the receiver plane;
   sidewalls of the secondary portion being inclined toward one another in a direction which is away from the secondary entrance aperture.

The solar radiation collector may be further embodied by any one or more of the following in combination, mutatis mutandis.

At least two sidewalls of the primary portion, adjacent to the primary receiver plane, may be planar, the sidewalls of the secondary portion being coplanar with them.

The secondary portion may be a prism. In addition, the primary and secondary portions may be integrally formed as a single prism.

The secondary portion may comprise at least one reflective surface, having at least one cross section comprising at least a parabolic portion (i.e., it's formed as a compound parabolic concentrator [CPC]).

The photovoltaic cell may project beyond the reflective surface.

The a first edge of the photovoltaic cell may be substantially coincident with a first edge of the secondary entrance aperture, the reflective surface being formed having a first section being an arc, and a second section being parabolic, such that:
the photovoltaic cell extends between a first end of the first section and a first end of the secondary entrance aperture of the secondary portion;
the second section extends between a second end of the first section and a second end of the secondary entrance aperture;
the focus of the parabolic of the second section is coincident with the first end of the first section; and
the acute angle formed between a first line extending along the secondary entrance aperture and a second line which is perpendicular to one which extends from the first end of the first section to the second end of the first section is equal to half of the acceptance angle of the secondary portion;
   the acceptance angle of the secondary portion being substantially equal to the exit angle of the primary portion.

The photovoltaic cell may be monofacial. Alternatively, it may be bifacial and transparent to infrared radiation, the solar radiation collector further comprising an up-conversion material adapted to reradiate light irradiating thereupon as radiation containing spectral components in the visible range, and disposed such that the reradiated light impinges upon the photovoltaic cell.

The photovoltaic cell may be substantially parallel to the primary entrance aperture.

The reflective surface of the secondary portion may be a dichroic filter adapted to allow at least infrared radiation to pass therethrough.

According to a still further aspect of the present invention, there is provided a solar array comprising a plurality of solar radiation collectors according to any of the aspects and/or embodiments above.

According to the above aspect, specifically when the solar radiation collectors are each embodied with a right-triangular cross-section as described above, the solar array may be embodied by any one of the following:
Primary entrance apertures of the solar radiation collectors may each be designed for being mounted oriented substantially horizontally, such that the edge of the primary receiver plane which contacts the primary entrance aperture is oriented along an east-west line, and the surface of the primary receiver plane which faces the interior of the primary portion faces the equator.
Primary entrance apertures of the solar radiation collectors may each be designed for being mounted oriented substantially vertically, such that the edge of the primary receiver plane which contacts the primary entrance aperture is oriented along an east-west line, and the surface of the primary receiver plane which faces the interior of the primary portion faces upwardly.

It will be appreciated that the solar radiation collector and/or the solar array according to any of the above aspects:
has a flat-panel form factor;
may be used as a non-tracking (i.e., static) concentrator;
requires no maintenance (besides cleaning) once installed;
may be designed for use in any location on Earth; and
with some designs, may achieve a concentration up to about 9 with the use of a bifacial photovoltaic cell.

### BRIEF DESCRIPTION OF THE DRAWINGS

In order to understand the invention and to see how it may be carried out in practice, embodiments will now be described, by way of non-limiting examples only, with reference to the accompanying drawings, in which:

FIGS. 1A and 1B are perspective and top views, respectively, of one example of a solar radiation collector;

FIGS. 1C and 1D are bottom perspective and bottom views, respectively, of an alternative example of a solar radiation collector;

FIGS. 1E and 1F are bottom perspective and bottom views, respectively, of another alternative example of a solar radiation collector;

FIG. 2A is a cross-sectional view of the solar radiation collector, taken along line II-II in FIG. 1A;

FIGS. 2B through 2D are close-up views of a second portion of a concentrator of the solar radiation collector illustrated in FIG. 2A;

FIG. 3A is a top view of the solar radiation collector illustrated in FIGS. 1A and 1B, shown during use;

FIG. 3B is a perspective view of the solar radiation collector illustrated in FIGS. 1A and 1B, indicating imaginary planes intersecting a primary entrance aperture thereof;

FIG. 4A illustrates a solar array comprising a plurality of the solar radiation collectors illustrated in FIGS. 1A through 3;

FIGS. 4B and 4C are cross-sectional views of the solar array taken along line IV-IV in FIG. 4A;

FIG. 5A is a cross-sectional view of the solar radiation collector, taken along line II-II in FIG. 1A, according to one modification thereof;

FIG. 5B is a close-up view of a second portion of a concentrator of the solar radiation collector illustrated in FIG. 5A;

FIG. 5C is a cross-sectional view of the solar radiation collector illustrated in FIGS. 5A and 5B, according to a further modification thereof;

FIG. 6 is a close-up view of the interface between the second portion of the solar radiation collector and a photovoltaic cell thereof, according to a modification;

FIGS. 7A, 8A, and 9A are top views of the solar radiation collector according to further modifications;

FIGS. 7B, 8B, and 9B illustrate solar arrays, each comprising a plurality of the solar radiation collectors illustrated in FIGS. 7A, 8A, and 9A, respectively;

FIG. 10A is a top view of a further example of a solar radiation collector;

FIG. 10B is a cross-sectional view of the solar radiation collector, taken along line VIII-VIII in FIG. 10A; and

FIG. 10C illustrates a solar array comprising a plurality of the solar radiation collectors illustrated in FIGS. 10A and 10B.

### DETAILED DESCRIPTION OF EMBODIMENTS

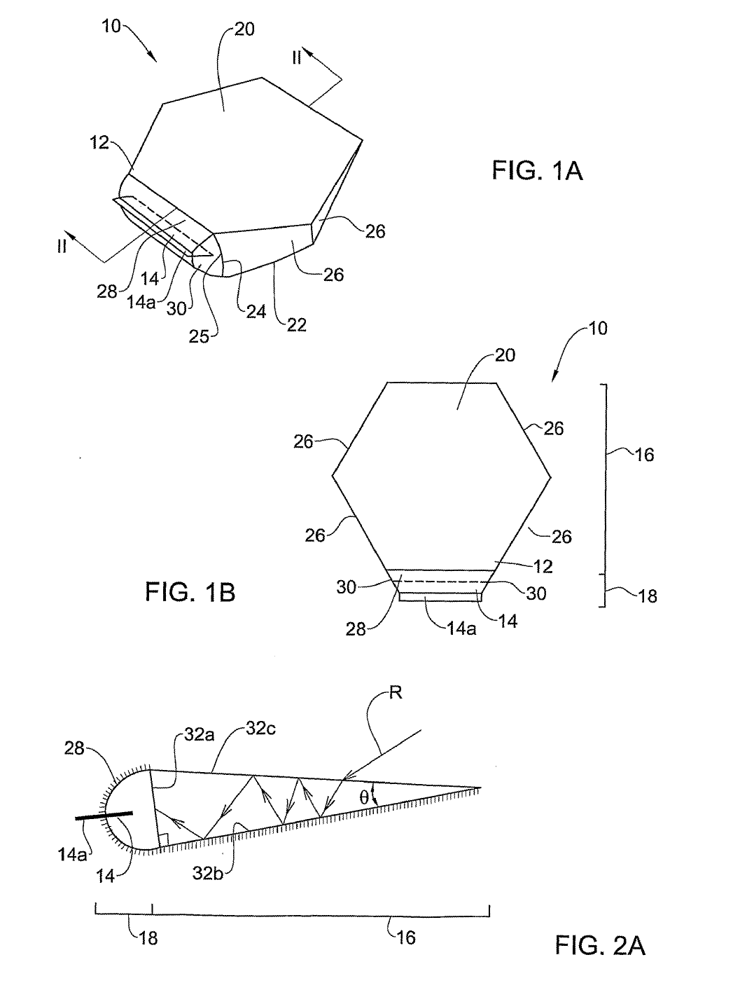

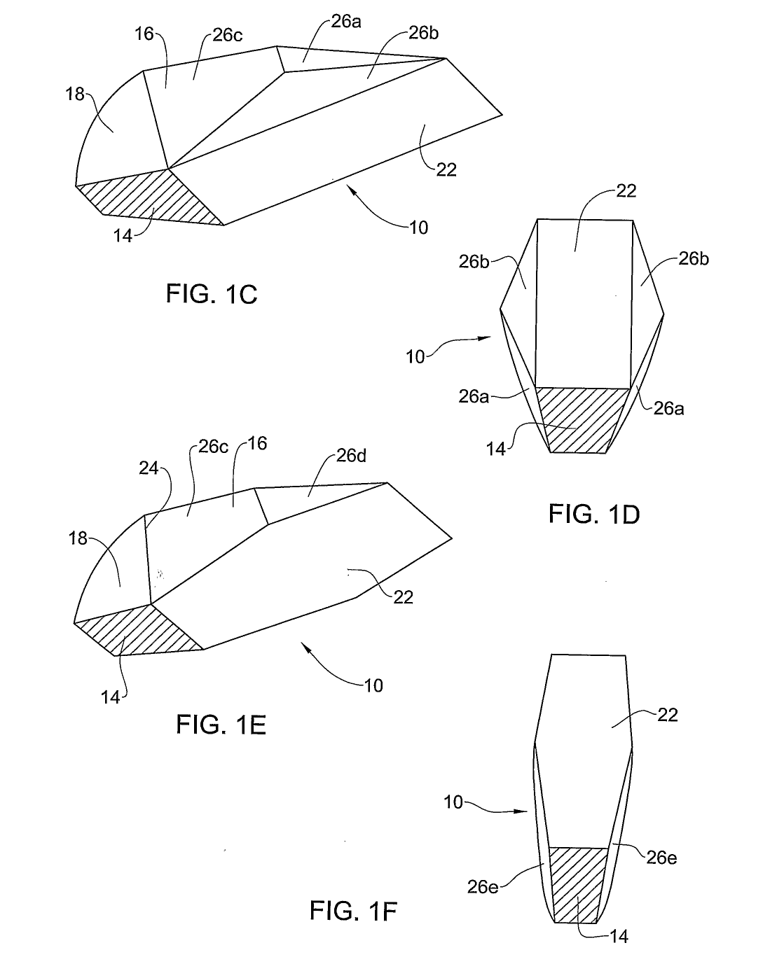

As illustrated in FIGS. 1A and 1B, there is provided a solar radiation collector, which is generally indicated at 10. The collector 10 comprises a concentrator 12, which is constituted by a prism, and a photovoltaic cell 14, which may be embedded therein. The concentrator 12 may be made from Poly Methyl Methacrylate (PMMA), or any other appropriate material. As indicated in FIG. 1B, the concentrator 12 comprises a primary portion 16 and an optional secondary portion 18.

The primary portion 16 is defined between a primary entrance aperture 20, which constitutes the top planar surface of the concentrator 12, a bottom reflecting surface 22, which is adapted to be highly reflective, for example by providing it with a highly reflective coating, and a primary receiver plane 24. In the embodiment illustrated in FIGS. 1A and 1B, the primary portion is formed so as to have a hexagonal shape in plan view. Sidewalls 26 of the primary portion 16 extend perpendicularly downward from the primary entrance aperture 20.

According to alternative examples, for example as illustrated in FIGS. 1C through 1E, at least some of the sidewalls 26 of the primary portion 16 extend downward from the primary entrance aperture 20 in a non-perpendicular manner, i.e., they are disposed such that they form an acute angle therewith. They may be straight or shaped as a parabolic reflector such as a CPC. They may be coated with a reflective material, or designed so as to totally internally reflect radiation impinging thereupon.

According to a first alternative example, as illustrated in FIGS. 1C and 1D, first portions, indicated at 26a (not seen in FIG. 1C), of some of the sidewalls extend downwardly from the primary entrance aperture 20 substantially perpendicularly or at a slight obtuse angle thereto. Second portions 26b, which are disposed at an acute angle to the primary entrance aperture 20, are disposed below the first portions 26a. In addition, the concentrator comprises rear-most sidewalls 26c which are disposed at an acute angle to the primary entrance aperture 20.

According to a first alternative example, as illustrated in FIGS. 1E and 1F, forward-most sidewalls 26d (not seen in FIG. 1E) of the concentrator extend downwardly from the primary entrance aperture 20 substantially perpendicularly or at a slight obtuse angle thereto. Rear-most sidewalls 26e thereof extend downwardly from the primary entrance aperture 20 such that they are disposed at an acute angle thereto.

According to either of the first examples, the concentration of the concentrator 12 is increased. In addition, a smaller photovoltaic cell 14 may be used.

It will be appreciated that while in the accompanying figures, the primary receiver plane 24 is indicated by a solid line, the primary receiver plane may not be physically distinguishable, e.g., the primary and secondary portions may be constituted by a continuous prism.

The secondary portion 18 comprises a reflective surface 28 which is adapted to be highly reflective, for example by providing with a highly reflective coating, and sidewalls 30, and a secondary entrance aperture 25, which, according to the present example, is coincident with the primary receiver plane 24 of the primary portion. The sidewalls 30 of the secondary portion 18 may be coplanar with the sidewalls 26 of the primary portion 16, i.e., are inclined toward one another in a direction away from the secondary entrance aperture 25 (thus, from a plan view, the secondary portion has is trapezoidal). The photovoltaic cell 14, which according to the present example is bifacial, is embedded within the secondary portion 18 along a secondary receiving plane thereof.

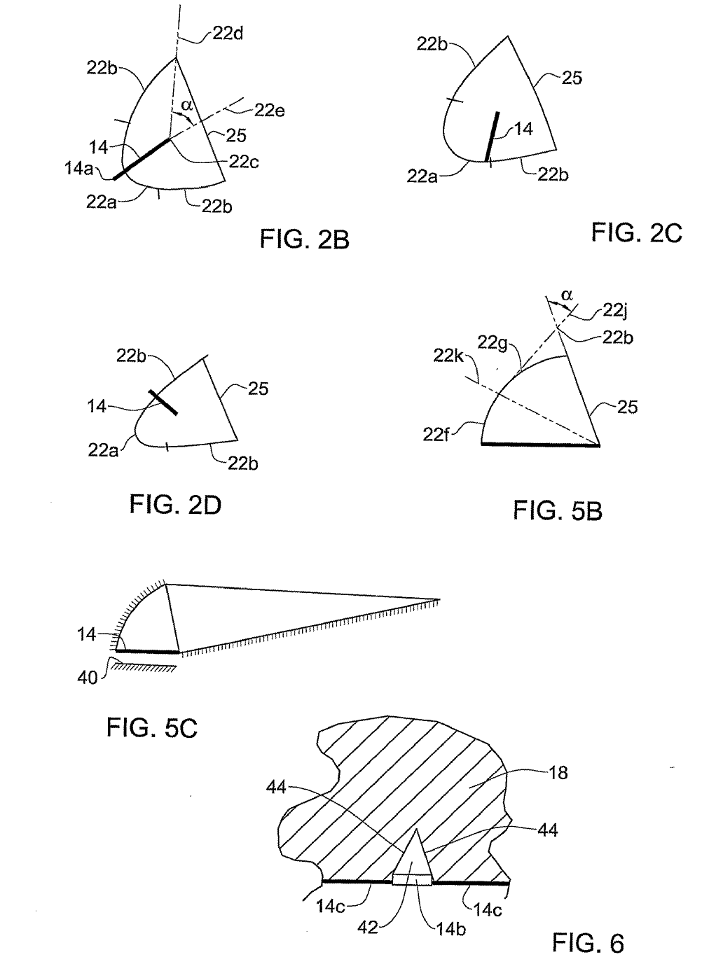

As best seen in FIG. 2A, the primary portion has a right-triangular cross-section, wherein a first cathetus 32a constitutes the primary receiver plane 24, a second cathetus 32b constitutes the bottom reflecting surface 22, and the hypotenuse 32c constitutes the primary entrance aperture 20. The reflective surface 28 of the secondary portion 18 is formed as compound parabolic concentrator (CPC), such as formed with a circular involute.

In addition, FIG. 2A illustrates how a ray R of radiation which enters via the primary entrance aperture is reflected via total internal reflection towards the primary receiver plane.

For example, as illustrated in more detail in FIG. 2B, the reflecting surface 22 may be formed having a central section, indicated at 22a, formed as a circular arc, and two parabolic sections 22b. The foci of the parabolas are coincident with one another, and with the center of the arc, as indicated at point 22c. This point 22c lies within the secondary portion. The secondary portion is further formed such that the acute angle a formed between a first line 22d connecting the center of the arc and a distal end of one of the parabolic sections and a second line 22e extending from the midpoint of the arc beyond the center thereof is equal to half of the acceptance angle of the secondary portion (the acceptance angle of the secondary portion should be designed to equal the exit angle of the primary portion). The photovoltaic cell 14 may lie along any radius of the central section 22a, such as illustrated in FIGS. 2C and 2D.

In addition, a projecting portion 14a of the photovoltaic cell 14 may project slightly beyond the vertex. The purpose for this will be explained below.

In selecting the angle between the second cathetus 32b and the hypotenuse 32c (i.e., the angle between the planes of the bottom reflecting surface 22 and the primary entrance aperture 20), as indicated by θ in FIG. 2A, the primary consideration is that radiation which enters via the primary entrance aperture will reflect within the primary portion 16 of the concentrator 12 until it reaches the primary receiver plane 24. In this way, the amount of rejected radiation is reduced. In order to ensure that this occurs, total internal reflection of radiation impinging on and entering through the primary entrance aperture 20 from within the prism should be ensured. To achieve this, the prism angle θ is determined by:

$$θ = \frac{{θ}_{c} - {sin}^{- 1} [ \frac{1}{n} sin ( \frac{π}{2} - {θ}_{a} ) ]}{2} , \qquad ( 1 )$$

where:
θ is the prism angle;
θ_{c} is the critical angle for total internal reflection of the prism;
n is refractive index of the prism; and
θₐ is the maximum acceptance elevation angle, in radians, of the sun at the location where the solar radiation collector is installed.

It is known, for example from Ideal Prism Solar Concentrators by D. R. Mills and J. E. Giutronich (published in Solar Energy, Vol. 21, pp. 423-430 by Pergamon Press, Ltd., Great Britain, the entire contents of which are incorporated herein by reference), that the concentration of the primary portion in this case is known to be given by:

$$C = \frac{1}{sin θ} . \qquad ( 2 )$$

where C is the concentration of the primary portion.

For a material having a refractive index of 1.5 and an acceptance angle of 90° (i.e., at the equator), C approaches 2.8.

Radiation which enters the primary receiver plane 24 impinges on the photovoltaic cell 14, either directly, or by being reflected off of the interior of the reflective surface 28. As the reflective surface 28 is formed as a parabola, the radiation is further concentrated, for example up to about 7%, which brings the total concentration to about 3.

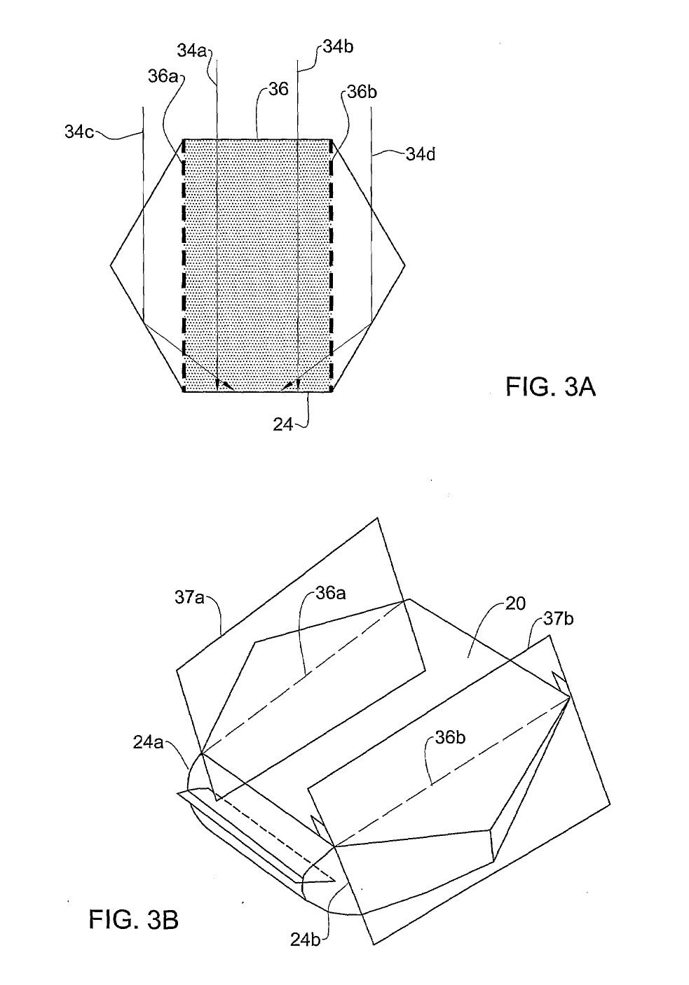

During use, as illustrated in FIG. 3A, radiation which enters the concentrator 12 via the primary entrance aperture 20 along a path which is in a plane perpendicular to the primary receiver plane 24, as indicated by arrows 34a and 34b (since FIG. 3A illustrates a top view of the solar collector, the radiation is shown as a straight line, even after having entered via the primary entrance aperture; it will be appreciated that in reality, the radiation is reflected within the receiver as shown in FIG. 2A), are reflected directly to the primary receiver plane. (For clarity, the secondary portion is not illustrated in FIG. 3.) This applies to all radiation which enters in the region 36 which is between the broken lines 36a and 36b. It will be appreciated that each of the broken lines 36a and 36b are the intersection between the plane of primary entrance aperture 20 and an imaginary plane 37a, 37b which is perpendicular to both the primary entrance aperture and an extreme end 24a, 24b of the primary receiver plane 24, as illustrated in FIG. 3B. Radiation which enters the concentrator via the primary entrance aperture outside region 36, as indicated by arrows 34c and 34d, is reflected off of the sidewalls 26 toward the primary receiver plane 24. This increases the concentration, as the amount of radiation which impinges on the photovoltaic cell per unit area thereof is increased due to the reduction in size of the cell. In addition, as the azimuth angle of the sun changes throughout the day, the radiation which enters the concentrator 12 typically does not enter along a path which is in a plane perpendicular to the primary receiver plane. Therefore, the exact shape of the primary entrance aperture, i.e., geometrical parameters such as the angles of the hexagon, may be designed so as to optimize the amount of radiation that reaches the primary receiver plane. This is dependent on the location that the solar radiation collector 10 is to be used. The parameters may be determined by computational means, such as ray tracing. Factors to consider when designing the shape of the primary entrance aperture include the overall system concentration, the cost of materials, the location of intended use, and desired efficiency.

As the photovoltaic cell 14 heats up during use due to the concentration of radiation thereon, the projecting portion 14a thereof may be used to cool it, for example by attaching cooling members (not illustrated), such as cooling fins, thereto that may be in thermal contact with a cold sink or ambient air.

In addition, the bottom reflecting surface 22 and/or the reflective surface 28 of the secondary portion 18 may be a dichroic filter, adapted to allow infrared radiation to pass therethrough, and to reflect at least light in the visible spectrum. According to this modification, the light which reaches the photovoltaic cell 14 will be cooler.

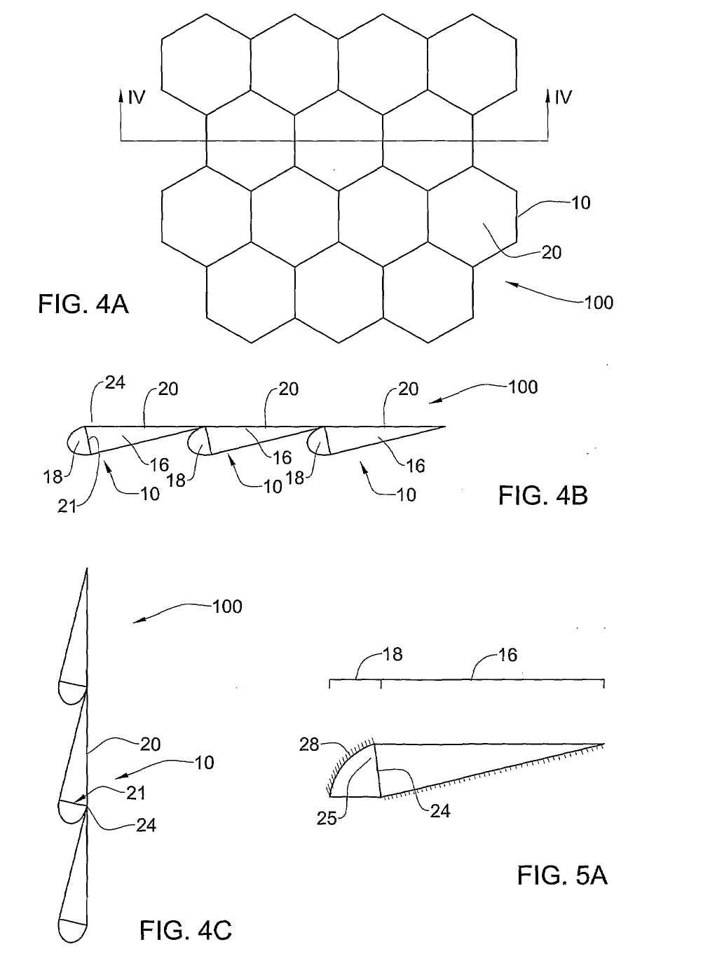

As illustrated in FIG. 4A, a plurality of the solar radiation collectors 10 can be tessellated together to form a solar array, generally indicated at 100. Due to the shape of the solar radiation collector 10, there are no gaps between the primary entrance apertures 20 of adjacent collectors, so all of the radiation impinging on the solar array enters one of the collectors. As illustrated in FIG. 4B, the secondary portion 18 of each solar radiation collector 10 lies below the solar radiation collector immediately adjacent thereto, due to the triangular cross-section of the primary portion 16. Thus, the secondary portion, which is not involved in direct collection of radiation, does not interfere in the tessellation of the primary entrance apertures 20.

The solar array may be mounted horizontally, as seen in FIG. 4B, such that the edge of each primary receiver plane 24 which contacts the primary entrance aperture 20 is oriented along an east-west line, and the surface 21 of the primary receiver plane which faces the interior of the primary portion faces the equator.

As illustrated in FIG. 4C, the solar array may be mounted vertically, such that the edge of each primary receiver plane 24 which contacts the primary entrance aperture 20 is oriented along an east-west line, and the surface of the primary receiver plane which faces the interior of the primary portion faces upwardly.

The non-limiting example described above with reference to FIGS. 1A through 3 may be modified.

For example, as illustrated in FIG. 5A, and in more detail in FIG. 5B, the cross-sectional shape of the reflective surface 28 of the secondary portion 18 may be formed as an asymmetric CPC having a first section, indicated at 22f, being in the form of an arc, and a second section, indicated at 22g, being in the form of a parabolic section, such that one end of the parabola is coincident with one end of the secondary entrance aperture 25, and the focus of the parabola is coincident with the other end of the acceptance place. In addition, the acute angle a formed between a first line 22h extending along the secondary entrance aperture 25, and a second line 22j which is perpendicular to one 22k which extends from the first end of the first section to the second end of the first section is equal to half of the acceptance angle of the secondary portion (the acceptance angle of the secondary portion should be designed to equal the exit angle of the primary portion). The photovoltaic cell 14, which may be monofacial or bifacial, extends along a secondary receiving plane which extends between a one end of the first section and the intersection between the bottom reflective surface 22 and the primary receiver plane 24 of the primary portion 16. It may lie along any angle, for example, being parallel to the primary entrance aperture 20. No projecting portion 14a of the photovoltaic cell 14 is necessary, as a cooling system may be in thermal contact with the underside thereof.

As illustrated in FIG. 5C, in the event that the photovoltaic cell 14 of the example illustrated in FIGS. 5A and 5B is bifacial, an up-conversion surface 40, which is made of a material adapted to reflect infrared radiation as radiation in the visible spectrum, is disposed below the photovoltaic cell and arranges such that radiation from the photovoltaic cell is reflected back theretoward. In use, any infrared radiation, which may account for about 25% of the total radiation which reaches the photovoltaic cell, passes therethrough (bifacial photovoltaic cells are known to be substantially transparent to infrared radiation) and impinges on the up-conversion surface 40. The infrared light irradiates the up-conversion material, and reradiates it as radiation containing spectral components in the visible range. The reradiated radiation impinges upon the bottom side of the photovoltaic cell 14, thus increasing the total amount of solar radiation which is converted into electricity. In addition, since the infrared radiation is ultimately converted into electricity, less waste heat is produced, and the photovoltaic cell 14 is heated less than it would otherwise. Although the up-conversion surface 40 illustrated in FIG. 5C is planar, it will be appreciated that it may be provided in any other desired shape, such as curved, etc.

As illustrated in FIG. 6, the surface of the secondary portion 18 which abuts the photovoltaic cell may be formed with grooves 42 above bus-bars 14b thereof. The grooves 42 are formed such that the surfaces 44 thereof reflect all radiation impinging thereon (i.e., total internal reflection). Thus, more light reaches active areas 14c of the photovoltaic cell 14, increasing the amount of electricity produced thereby.

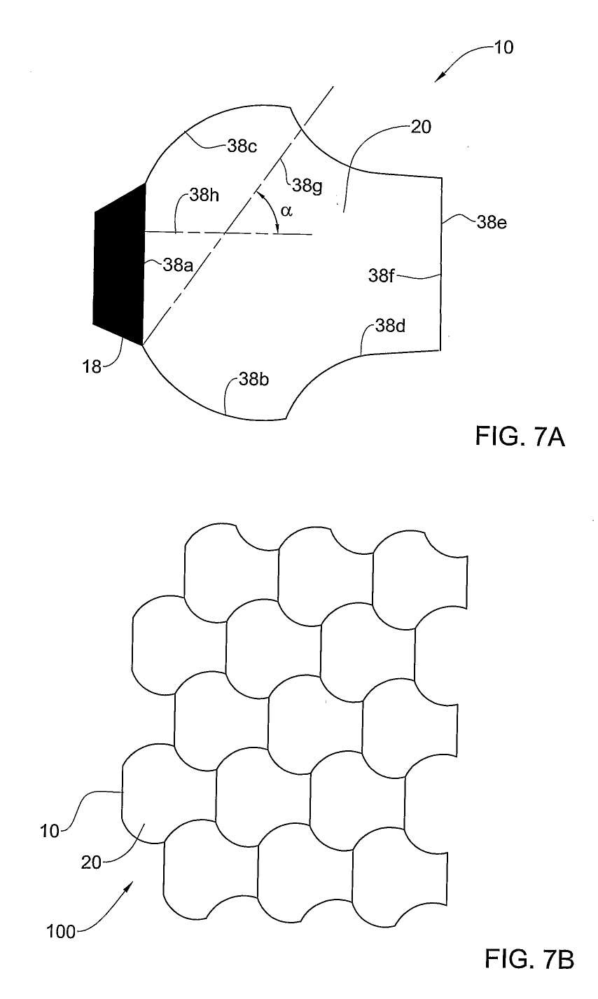

As illustrated in FIGS. 7A through 9B, the primary entrance aperture 20 may have a shape other that that described above with reference to FIGS. 1A through 3. For example, as illustrated in FIG. 7A, the sides of the primary entrance aperture may comprise a first side 38a which constitutes the top edge of the primary receiver plane, second and third sides 38b, 38c which are formed as parabolic sections, fourth and fifth sides 38d and 38e which are formed as complementary to the second and third sides, and a sixth side 38f which is parallel to and equal in length to the first side. As illustrated in FIG. 7A, the focus of the parabola of the second side 38b is coincident with the intersection between the third on first sides. The acute angle formed between a first line 38g from the focus of the second side 38b and the intersection between the second and fourth sides and a second line 38h which is perpendicular to the first side is equal to half the acceptance angle of the primary portion. (The secondary portion 18 is indicated for reference.) It will be appreciated that the sidewalls of the solar concentrator illustrated in FIG. 7A constitute a compound parabolic concentrator.

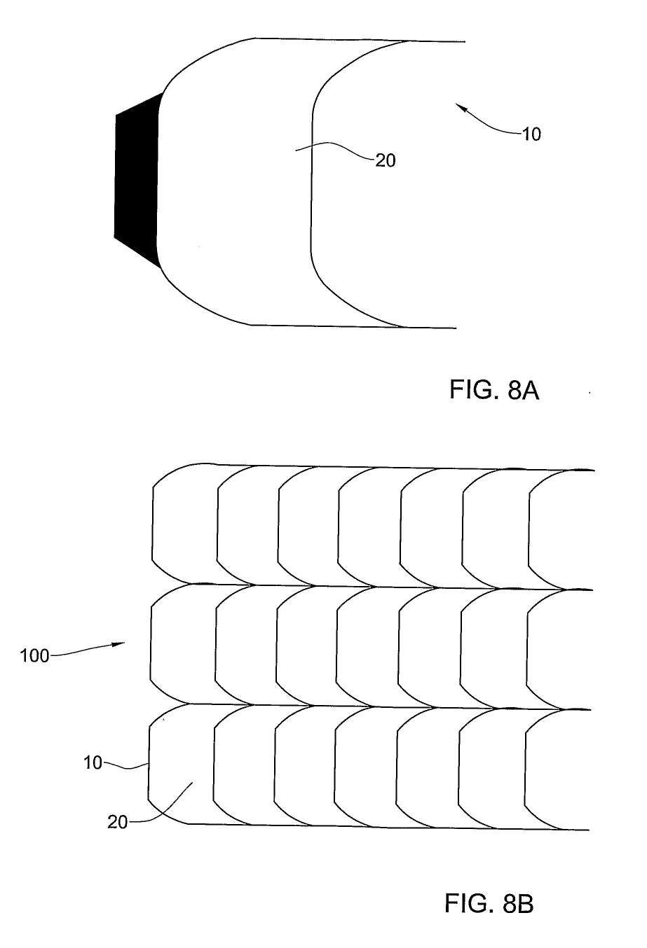

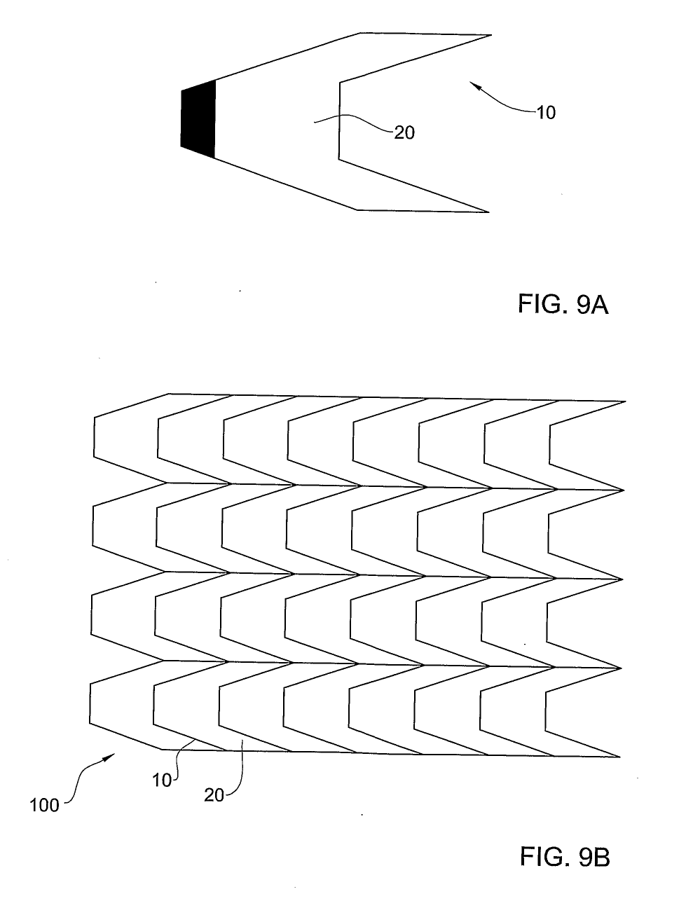

FIGS. 8A and 9A illustrate other possible designs for primary entrance apertures 20 for solar concentrators 10, with the secondary portions 18 of each being indicated for reference.

As illustrated in FIGS. 7B, 8B, and 9B, a plurality of solar radiation collectors, each as illustrated in one of FIGS. 7A, 8A, and 9A, respectively, may be tessellated to form a solar array 100, with no gaps between adjacent solar radiation collectors 10.

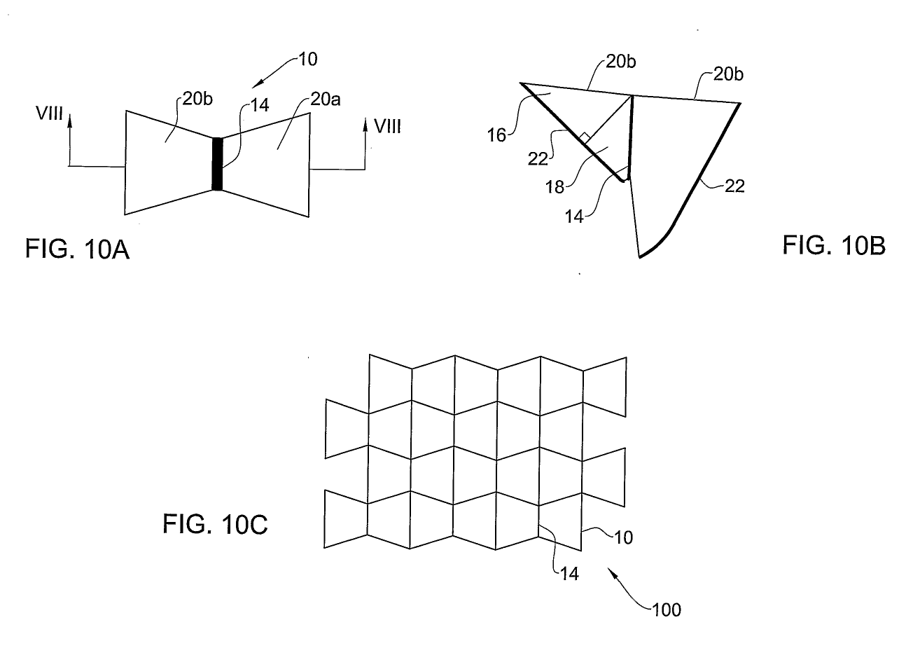

According to another example, as illustrated in FIGS. 10A and 10B, the primary entrance aperture 20 of the solar radiation collector 10 may be formed in two parts 20a and 20b, each being formed as identical equilateral trapezoids, arranged such that their respective short parallel sides are coincident with one another. The photovoltaic cell 14 extends downwardly from the coincident short parallel ends.

As seen in FIG. 10B, one sides of the collector are formed having a first section 16, having a planar primary entrance aperture 20b, a bottom reflective surface 22, and a primary receiver plane 24 (indicated be a broken line in FIG. 10B), arranged similarly as described above with reference to FIG. 2. The secondary portion 18 is defined between the primary receiver plane 24 and the photovoltaic cell 14. The other side is formed as having a bottom reflective portion 22 angled so as to reflect radiation approaching from the other side directly toward the photovoltaic cell 14.

As illustrated in FIG. 10C, a plurality of solar radiation collectors, each as illustrated in FIG. 10A, may be tessellated to form a solar array 100, with no gaps between adjacent solar radiation collectors 10. In use, the array is oriented so that the photovoltaic cells 14 (indicated by broken lines in FIG. 10C) lie along east-west lines.

Those skilled in the art to which this invention pertains will readily appreciate that numerous changes, variations and modifications can be made without departing from the scope of the invention mutatis mutandis.

1-53. (canceled)

54. A solar radiation collector comprising a concentrator and a photovoltaic cell, said concentrator comprising at least a prismatic primary portion, said primary portion comprising:
a primary entrance aperture having a perimeter, an outer surface adapted for receiving radiation, and a inner surface;
a primary receiver plane;
sidewalls, meeting said primary entrance aperture along at least a portion of said perimeter; and
a reflective bottom surface; and
being adapted to utilize total internal reflection at least from said inner surface of the primary entrance aperture to concentrate radiation entering through said primary entrance aperture toward said primary receiver plane;
wherein said primary entrance aperture comprises a reference area defined as the area thereof between two lines, each of said lines being the intersection between the primary entrance aperture and an imaginary plane which is perpendicular to both the primary entrance aperture and an extreme end of the primary receiver plane; the total area of said primary entrance aperture substantially exceeding that of said reference area.

55. A solar radiation collector according to claim 54, further comprising a prismatic secondary portion, said secondary portion:
having a secondary entrance aperture which is substantially coincident with said primary receiver plane;
comprising said photovoltaic cell; and
being adapted for directing radiation entering via said secondary entrance aperture toward said photovoltaic cell.

56. A solar radiation collector according to claim 55, wherein said primary and secondary portions are integrally formed as a single prism.

57. A solar radiation collector according to claim 55, said photovoltaic cell being bifacial, the reflective surface of the secondary portion being formed having a central section, formed as a circular arc and two parabolic sections, such that:
the foci of the two parabolic sections are coincident with one another and with the center of the arc and are within the secondary portion;
a proximal end of each of said parabolic sections is coincident with one end of the central section;
a distal end of each of said parabolic sections is coincident with one end of the reflective plane;
the acute angle formed between a first line connecting the center of the arc and a distal end of one of the parabolic sections and a second line extending from the midpoint of the arc beyond the center thereof is equal to half of the acceptance angle of the secondary portion; and
the photovoltaic cell extends at least from the center of the arc to a point of the central section of the reflective surface;
the acceptance angle of the secondary portion being substantially equal to the exit angle of the primary portion.

58. A solar radiation collector according to claim 55, a first edge of said photovoltaic cell being substantially coincident with a first edge of the secondary entrance aperture, said reflective surface being formed having a first section being an arc, and a second section being parabolic, such that:
said photovoltaic cell extends between a first end of the first section and a first end of the secondary entrance aperture of the secondary portion;
said second section extends between a second end of the first section and a second end of the secondary entrance aperture;
the focus of the parabolic of the second section is coincident with said first end of the first section; and
the acute angle formed between a first line extending along the secondary entrance aperture and a second line which is perpendicular to one which extends from the first end of the first section to the second end of the first section is equal to half of the acceptance angle of the secondary portion;
the acceptance angle of the secondary portion being substantially equal to the exit angle of the primary portion.

59. A solar radiation collector according to claim 58, wherein said photovoltaic cell is bifacial and transparent to infrared radiation, said solar radiation collector further comprising an up-conversion material adapted to reradiate light irradiating thereupon as radiation containing spectral components in the visible range, and disposed such that the reradiated light impinges upon the photovoltaic cell.

60. A solar radiation collector according to claim 55, wherein said reflective surface of the secondary portion is a dichroic filter adapted to allow at least infrared radiation to pass therethrough.

61. A solar radiation collector according to claim 55, wherein sidewalls of the secondary portion incline toward one another in a direction which is away from the secondary entrance aperture.

62. A solar radiation collector according to claim 54, wherein the primary entrance aperture is formed as a hexagon having a first side coincident with an edge of the primary receiver plane, and second and third sides each coincident with an edge of one of the sidewalls and constituting adjacent sides thereof, said first side being between said second and third sides.

63. A solar radiation collector according to claim 54, wherein the primary entrance aperture of the solar radiation collector is of a shape which comprises at least four sides, wherein a first side is coincident with an edge of the primary receiver plane, and second and third sides, each coincident with an edge of one of the sidewalls, are each adjacent to said first side at proximal ends thereof, and are each formed as a parabolic section, such that:
the focus of the parabola forming the second side is coincident with the intersection between the first and third sides;
the focus of the parabola forming the third side is coincident with the intersection between the first and second sides; and
the acute angle formed between a first line extending between the proximal end of the second side and the focus of the second side and a second line extending perpendicularly to the first side is equal to half of the acceptance angle of the primary portion.

64. A solar radiation collector according claim 54, wherein at least a part of at least one of said sidewalls is disposed such that is forms an acute angle with the primary receiver aperture.

65. A solar radiation collector according to claim 54, wherein said primary entrance aperture is of a shape which may be tessellated with other solar radiation collectors having the same shape without leaving gaps therebetween.

66. A solar radiation collector according to claim 54, wherein said bottom reflective surface is a dichroic filter adapted to allow at least infrared radiation to pass therethrough.

67. A solar radiation collector according to claim 54, wherein said primary portion has a cross-section, taken along a plane which is perpendicular to said primary receiver plane, which is right-triangular, such that:
a first cathetus thereof is coincident with the primary receiver plane;
a second cathetus thereof is coincident with the reflective bottom surface; and
the hypotenuse thereof is coincident with the primary entrance aperture.

68. A solar radiation collector according to claim 67, wherein the angle between the hypotenuse and the second cathetus is given by:
$$θ = \frac{{θ}_{c} - {sin}^{- 1} [ \frac{1}{n} sin ( \frac{π}{2} - {θ}_{a} ) ]}{2} ,$$
where:
θ is the angle between the hypotenuse and the second cathetus;
θ_{c} is the critical angle for total internal reflection of the prism;
n is the refractive index of the prism; and
θₐ is the maximum acceptance elevation angle, in radians, of the sun at the location where the solar radiation collector is installed.

69. A solar radiation collector according to claim 54, wherein said primary portion has a cross-section, taken along a plane which is perpendicular to said primary receiver plane, which is right-triangular, such that:
a first cathetus thereof is coincident with the primary entrance aperture;
a second cathetus thereof is coincident with the primary receiver plane; and
the hypotenuse thereof is coincident with the reflective bottom surface.

70. A solar radiation collector according to claim 69, wherein the angle between the hypotenuse and the second cathetus is given by:
$$θ = \frac{{θ}_{c} - {sin}^{- 1} [ \frac{1}{n} sin ( \frac{π}{2} - {θ}_{a} ) ]}{2} ,$$
where:
θ is the angle between the hypotenuse and the second cathetus;
θ_{c} is the critical angle for total internal reflection of the prism;
n is the refractive index of the prism; and
θₐ is the maximum acceptance elevation angle, in radians, of the sun at the location where the solar radiation collector is installed.

71. A solar array comprising a plurality of solar radiation collectors according to claim 54.

72. A solar array according to claim 71, wherein said primary entrance apertures of the solar radiation collectors are each designed for being mounted oriented substantially horizontally, such that the edge of the primary receiver plane which contacts the primary entrance aperture is oriented along an east-west line, and the surface of said primary receiver plane which faces the interior of the primary portion faces the equator.

73. A solar array according to claim 72, wherein said primary entrance apertures of the solar radiation collectors are each designed for being mounted oriented substantially vertically, such that the edge of the primary receiver plane which contacts the primary entrance aperture is oriented along an east-west line, and the surface of said primary receiver plane which faces the interior of the primary portion faces upwardly.
